(19) United States
(12) Patent Application Publication
(10) Pub. No.: US 2012/0053761 A1
(43) Pub. Date: Mar. 1, 2012

(54) SYSTEM FOR PROCESSING REDUNDANT SIGNALS, ASSOCIATED METHOD, AND AIRCRAFT COMPRISING SUCH A SYSTEM

(75) Inventors: Remy DAYRE, Pibrac (FR); Gregory Schott, Roqueseriere (FR); Pierre Fabre, Tournefeuille (FR)

(73) Assignee: AIRBUS OPERATIONS (S.A.S.), TOULOUSE CEDEX (FR)

(21) Appl. No.: 13/212,549

(22) Filed: Aug. 18, 2011

(30) Foreign Application Priority Data
Aug. 24, 2010 (FR) 10 56737

(51) Int. Cl. G05D 1/00; H03K 17/00

(52) U.S. Cl. 701/3; 327/99

(57) ABSTRACT

This invention relates to a system for processing redundant signals, an associated method, as well as an aircraft comprising such a system, from a viewpoint of monitoring and passivation of erratic or oscillating failures affecting the sources of these redundant signals.

The system comprises a module for calculation of a current useful signal from redundant signals; a monitoring/passivation module, able to detect an erroneous signal and to exclude the said erroneous signal from the calculation according to a criterion; and a means for toggling, as soon as an erroneous signal is detected, to a freeze mode freezing the output useful signal, and for returning, as soon as an erroneous signal no longer is detected, to a transmission mode where the current useful signal is transmitted as output useful signal.

This application claims the priority of the French patent application No. 10 56737 of Aug. 24, 2010, which is incorporated herein by reference.

### FIELD OF THE INVENTION

This invention relates to a system for processing redundant signals, an associated method, as well as an aircraft comprising such a system, from a viewpoint of monitoring and passivation of erratic or oscillating failures affecting the sources of these redundant signals.

### Context of the Invention

Many systems nowadays use several redundant signals representative of the same physical magnitude and originating from several sources. This is the case in particular of on-board systems in means of transport, such as, for example, the systems of electrical flight controls provided for aircraft.

The use of several redundant sources actually greatly enhances the reliability of the systems using them.

For reasons of conciseness, although the invention applies to any type of system, it subsequently will be illustrated mainly in reference to such systems of electrical flight controls.

FIG. 1 thus schematically shows a computer 1 of an electric flight control system for aircraft 2. Computer 1 acquires instructions {Ci} originating from the pilots, such as the position of the control stick, then translates them (block 10) into control objectives {Oi}.

Similarly, measurements of values representative of physical magnitudes, such as anemometric and/or GPS and/or inertial measurements are carried out with the aid of sensors 20 of the aircraft. On the Figure and subsequently, only one value among all the values that are managed is shown and taken into account, marked X, although the invention also applies when several values are taken into account.

The control objectives {Oi} and the values X are used by flying laws 11 for calculating appropriate control surface commands {OGi} to be applied to the control surfaces of aircraft 2.

As the system of electrical flight controls is critical, computer 1 which it integrates acquires the same physical magnitude X with the aid of several redundant sources 20, generally through a double or triple redundancy. The values acquired from these redundant sources are shown on the Figure in the form of signals {X1, . . . XN}.

The use of redundant signals makes it possible to consolidate the useful value X passed into flying laws 11 by using principles of monitoring and passivation of sources 20, implemented by a system for processing redundant signals 12.

Monitoring of failures in the sources by module 12 is carried out by analysis of the redundant signals {X1, . . . XN} generally with a view to determining and excluding a signal that proves to be erroneous during a predetermined period, marked T (and therefore exclusion of the associated faulty source).

Passivation of the sources consists in limiting the effect of such a failure in order to avoid, for example, saturation departure (or “embarkation”) of the value X.

These mechanisms have been taken up in part in the publication “Evaluation of time-varying availability in multi-echelon spare parts systems with passivation,” Hoong Chuin Lau et al., 2004.

By way of illustration, in the control laws computers 1, monitoring of the sources may assume the form of a comparison, among them, of signals {X1, . . . XN} originating from different redundant sources, for example by determining the deviation between each of these signals and a linear combination thereof. A failure then is declared and the corresponding source excluded when this deviation for one of the signals exceeds a certain tolerance (or monitoring threshold) during the period T.

In order to limit the effect of the failure on flying laws 11 and on the performance of airplane 2 during the time (T) necessary for the detection of the failure, the passivation algorithms for failures then are implemented.

These consist, for example, in freezing, for a time T+ε the useful value A at instant t0 of detection of a deviation of one source with the others. In this way, the useful value at instant t is that of instant t0 if t0<t<t0+T+ε. At the end of the window T+ε, the useful signal again becomes the current signal.

These mechanisms, however, are not always adapted for the monitoring and passivation of erratic or oscillating failures affecting the signals from the sources {X1, . . . XN}.

For example, in the case where a redundant signal proves to be alternately valid and erroneous during a period T, the monitoring mechanisms of the state of the art are not going to trigger any failure detection or exclusion of the corresponding source, because no signal will have been erroneous during the entire period T.

Thus, at the end of period T, the useful value X itself also might well be erroneous because of taking into account the current alternately erroneous signal. The monitoring and passivation mechanisms therefore prove to be insufficiently robust as regards the different types of existing failures, in particular erratic or oscillating.

### SUMMARY OF THE INVENTION

This invention is intended to overcome this drawback by proposing in particular a system for processing redundant signals, comprising:
inputs for receiving a plurality of redundant signals originating from sources;
a module for calculation of a current useful signal from input redundant signals;
a module for monitoring and passivation of sources, able to detect an erroneous signal taken into account in the said calculation, and to exclude the said erroneous signal from the calculation according to at least one criterion (for example the period T mentioned above); and
an output for transmitting, as output useful signal, the said calculated current useful signal when no erroneous signal is detected;

characterized in that it further comprises, a means for toggling, as soon as an erroneous signal is detected, to a freeze mode where the output useful signal is frozen as output, and for returning, as soon as an erroneous signal no longer is detected, to a transmission mode where the calculated current useful signal is transmitted as output useful signal.

This invention thus offers more effective monitoring and passivation mechanisms. In fact, the monitoring according to the invention always assures the detection and exclusion of faulty sources, while the passivation is clearly improved through the use of the means for toggling.

This results in particular from that fact that henceforth toggling between the freeze mode of the output useful signal and the transmission mode of the calculated useful signal is triggered in “real time,” that is to say as soon as a failure (fault) is detected or eliminated.

In this way it is assured that no output useful signal results from a calculation performed on an erroneous input signal, unlike the known techniques less robust as regards erratic or oscillating type failures.

In order to increase the robustness of the system, it may be provided that the system comprises means for determining, on a sliding time window, a magnitude representative of the time during which the system is in freeze mode so as to exclude from the calculation, as soon as this magnitude reaches an exclusion threshold value, at least one signal detected as erroneous during the period of the said window.

Unlike the known techniques, this arrangement makes it possible to definitively exclude a faulty source while it is undergoing an erratic or oscillating type failure. This exclusion then makes it possible to perform the calculations of the current useful signal again with the aid of reliable sources only. The exclusion threshold value may be adjusted in order to regulate the sensitivity of the exclusion mechanisms according to the frequency of the erratic or oscillating failures.

This increased robustness proves to be particularly effective when the output useful signal is used as feedback reference in a third-party system. In fact, in the absence of this determination mechanism, the output useful signal might be quasi-frozen in time, possibly leading to a divergence of commands by virtue of the feedback loop.

In particular, the monitoring and passivation module is arranged for determining, on the sliding time window, a magnitude representative of the time during which a signal is detected as erroneous, so as to exclude from the calculation the signal detected as erroneous as soon as this magnitude reaches the said exclusion threshold value.

This arrangement assures a more precise identification of the erroneous signal and therefore of the source to be excluded, because a counter for the time (i.e. the said magnitude) may be assigned to each input signal.

In one embodiment, the monitoring and passivation module comprises a means able to generate, for at least one input signal, a Boolean representative of an erroneous state or non-erroneous state of the input signal.

This arrangement makes it possible to obtain a tool (the Boolean) effective both for controlling the passivation mechanisms (toggling) and the monitoring (exclusion) mechanisms in particular in the presence of erratic or oscillating failures, because this Boolean makes it possible to easily set up statistics from which decisions may be made.

In fact, according to a specific characteristic of the invention, the Boolean of an input signal controls a counter counting the said magnitude on the sliding time window, and the monitoring and passivation module comprises a comparator of the counter with the exclusion threshold value in order to generate, for the calculation module, a signal for exclusion of the input signal associated with the counter.

The use of a counter controlled by the Boolean generated in this way proves to be not very complex to implement, just as easily through software instructions as through hardware circuits.

That results in particular from an implementation in which it is provided that the counter comprises:
a switch controlled by the Boolean between a position connected to a register equivalent to “1” and a position connected to a register equivalent to “0”;
an adder receiving, as input, the output value of the switch and the output value of the counter, so as to increment the counter according to the Boolean;
a delay equal to the period of the sliding time window and receiving, as input, the output value of the switch;
a subtracter for subtracting, at the output of the adder, the delayed value as output of the delay and in this way producing an output value of the counter.

In this arrangement, the counter is implemented with the aid of logics relatively simple to use.

According to one characteristic of the invention, the monitoring and passivation module comprises a counter associated with each input signal and is set up to generate a Boolean representative of an erroneous state for each input signal. In that way, it is easy to identify the input signal (and therefore the source) to be excluded by reason of erratic or oscillating failure.

As a variant, when two input signals are taken into account during the said calculation, the monitoring and passivation module comprises a sole counter and is set up to generate a sole Boolean representative of an erroneous state common to the two input signals. This arrangement limits the resources used and is adapted to the case of a double redundancy where the errors are determined relative to the two acquired values. In fact, in this case, both values generally are declared as erroneous together.

In one embodiment, the means able to generate a Boolean representative of an erroneous state of an input signal comprises a comparator the output of which corresponds to the said Boolean and comparing the deviation between the said input signal and a reference signal calculated from the said input signals, with a tolerance threshold value. The reference signal in particular may be equal to the calculated current useful signal or use separate calculations. It is to be noted that the deviation may be obtained by the simple use of a subtraction logic in the presence of only two input redundant signals. This embodiment also proves to be simple to implement.

In particular, the monitoring and passivation module comprises a logic function OU receiving, as input, the Booleans representative of an erroneous state of the input signals taken into account in the calculation and generating, as output, a signal for control of the means for toggling. This logic, simple to implement, makes it possible to obtain a sole signal effectively controlling the mechanisms for passivation of failures according to the invention.

In one embodiment of the invention, the means for toggling comprises a switch controlled by the monitoring and passivation module, for switching, to the said output, the output useful signal for the freeze mode and the calculated current useful signal for the transmission mode. By way of example, in the freeze mode, the switch may loop onto itself a module for output of the useful signal.

In particular, the means for toggling may further comprise a slope limiter able to carry out a controlled transition between the frozen output useful signal and the calculated current useful signal during a toggling to transmission mode. This arrangement makes it possible to avoid excessively abrupt transitions when, for example, the current useful signal resulting from the exclusion of a source clearly differs from the output useful signal that has been frozen during the monitoring period having led to this exclusion.

Correlatively, the invention relates to a method for processing redundant signals, comprising the following steps:
receiving, as input, a plurality of redundant signals originating from sources;
calculating a current useful signal from input redundant signals;
detecting at least one erroneous signal taken into account in the said calculation, and excluding the said erroneous signal from the calculation when at least one criterion is met; and
transmitting, as output useful signal, the said calculated current useful signal when no erroneous signal is detected;

characterized in that it comprises:

as soon as an erroneous signal is detected, a step consisting in freezing the output useful signal, and

as soon as an erroneous signal no longer is detected, a step consisting in going back to a transmission mode where the calculated current useful signal is transmitted as output useful signal.

The method has advantages similar to those of the processing system set forth above, and particularly the fact that the output useful signal never is corrupted by an erroneous input signal that might have been taken into account during the said calculation.

Optionally, the method may comprise steps relating to the characteristics of the system described above.

In particular, the method may comprise a step of determining, on a sliding time window, a magnitude representative of the time during which a signal is erroneous, so as to exclude the erroneous signal from the calculation as soon as this magnitude reaches an exclusion threshold value.

Furthermore, there may be provided the generation, for at least one input signal, of a Boolean representative of an erroneous or non-erroneous state of the input signal; the use of this Boolean for updating a counter counting the said magnitude on the sliding time window, and the comparison of the counter with the exclusion threshold value for generating a signal for exclusion of the input signal associated with the counter; the use of this Boolean for controlling a switch provided for switching as output the output useful signal for the freeze mode and the calculated current useful signal for the transmission mode.

The system also relates to a system of electrical flight controls for an aircraft, comprising a computer receiving instructions and redundant signals originating from sources, the said computer comprising a flying laws module receiving information items corresponding to the instructions and at least one useful signal for generating control-surface commands for the aircraft, and comprising a processing system such as described above able to process the received redundant signals in order to generate the said useful signal as input of the flying laws module.

The invention also relates to an aircraft comprising a system of electrical flight controls, such as described above.

The system of electrical flight controls and the aircraft have advantages similar to those of the processing system set forth above, and optionally may comprise means relating to the characteristics of the processing system described above.

### BRIEF DESCRIPTION OF THE FIGURES

Other features and advantages of the invention also will become apparent in the description below, illustrated by the attached drawings, in which:

FIG. 1 shows a system of electrical flight controls for an aircraft;

FIG. 2 schematically illustrates a system for processing redundant signals in accordance with this invention;

FIG. 3 illustrates the determination of a reference signal in case of triple redundancy, implemented in the system of FIG. 2;

FIG. 4 schematically shows an output module of the processing system of FIG. 2;

FIG. 5 shows a module for monitoring an X1 signal, incorporated into the system of FIG. 2, in the case of a triple redundancy;

FIG. 6 schematically shows components of a system for processing redundant signals according to the invention in the case of a triple redundancy;

FIG. 7 illustrates an exclusion module of the system of FIG. 2, provided for determining whether an input signal must be excluded;

FIG. 8 schematically shows a system for processing redundant signals according to the invention in the case of a triple redundancy but using only two input signals for generating an output useful signal;

FIG. 9 shows a system for processing redundant signals according to the invention in the case of a multiple redundancy; and

FIG. 10 shows a system for processing redundant signals according to the invention in the case of a double redundancy.

### DETAILED DESCRIPTION OF EMBODIMENTS OF THE INVENTION

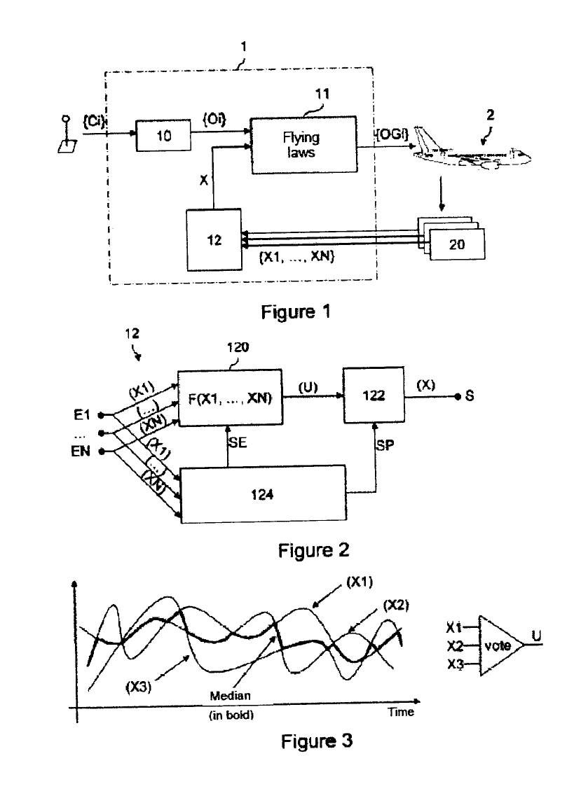

FIG. 2 schematically illustrates a system for processing redundant signals according to one embodiment of the invention. The system of FIG. 2 may consist in particular of a system 12 forming part of a computer for electrical flight controls of FIG. 1.

System 12 comprises inputs E1, . . . , EN for receiving the plurality of redundant signals X1, . . . , XN originating from sources 20, a module for calculation 120 of a current useful signal U from input redundant signals, for example according to a function F: U=F(X1, . . . , XN), an output module 122 connected to calculation module 120 for transmitting, as output useful signal (X), the said calculated current useful signal (U) in a normal transmission mode M1.

Module 120 for calculation of the current useful signal U may use different techniques for calculating the signal or for selecting a representative signal from among the redundant signals X1, . . . , XN as input.

FIG. 3 illustrates, for example, the selection of a median signal when the input redundant signals are three in number: X1, X2 and X3.

In this example, module 120 performs a vote among the three input signals, consisting in taking, at a given instant, as reference value (and therefore as current useful value U) the median value among the three values corresponding to the input signals. The median value is in particular the one that is included between the other two (in bold on the Figure).

In the case of a double redundancy (only two input signals X1 and X2), the reference value U may be an average of the two.

In general, calculation module 120 also may use a linear function of the input signals X1, . . . , XN (for example the average value

$$\frac{\sum {X}_{i}}{N} ) .$$

Reverting to FIG. 2, the system also comprises a module 124 for monitoring and passivation of the sources receiving as input the redundant signals X1, . . . , XN and generating a passivation signal SP at output module 122 as soon as it detects that a redundant signal X1, . . . , XN taken into account in the said calculation is erroneous, and generating a signal for exclusion SE of a redundant signal X1, . . . , XN as soon as this detection of the erroneous signal satisfies at least one criterion, for example a time quota in a sliding time window of period T, as will be seen subsequently.

As a variant, this exclusion may be triggered immediately in case of an overly significant error in the signal (disproportionate amplitude, etc.).

Output module 122 comprises in particular a means for toggling upon reception of a passivation signal SP indicating that an erroneous signal has been detected, to a freeze mode M2 where the output useful signal X is frozen as output S, and for returning, in the absence of passivation signal SP (therefore as soon as an erroneous signal no longer is detected), to transmission mode M1 where the calculated current useful signal U is transmitted as output useful signal X.

In general, the different modules described here may be cadenced by the same clock so that in one clock cycle (from t−1 to t), all the calculations are carried out. By way of illustration, the passivation signal SP thus is updated at each clock cycle.

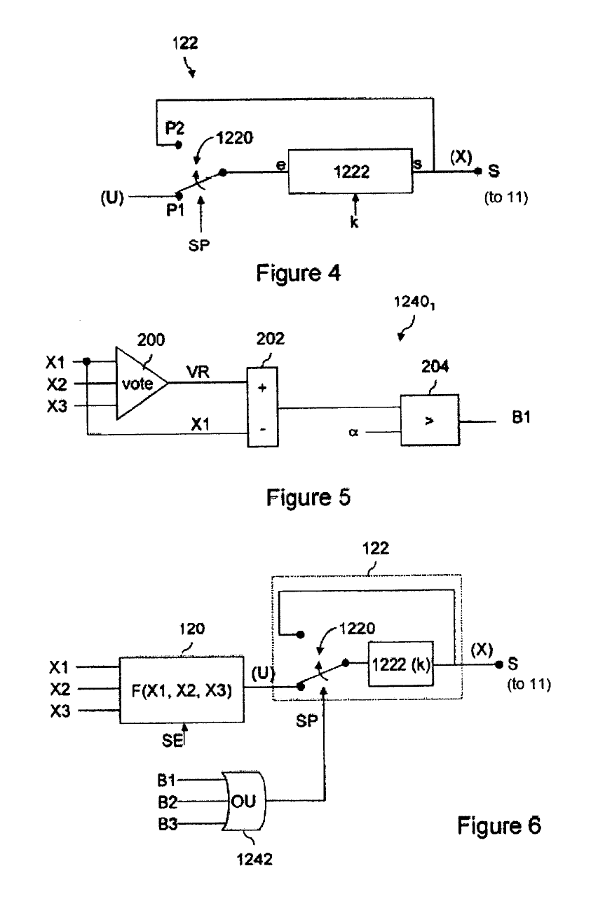

FIG. 4 illustrates an embodiment of output module 122, comprising a switch 1220 controlled by the passivation signal SP originating from module 124 and a slope limiter 1222.

In transmission mode M1 (absence of signal SP or zero signal), switch 1220 is in position P1 for supplying, as input of limiter 1222, the current useful signal U calculated by module 120. In stationary operation, that is to say as soon as its output value s=X equals that of input e, limiter 1222 transmits the signal as input, limiting its rate of change to a maximum value.

In freeze mode M2 (in the presence of a signal SP or non-zero signal), switch 1220 switches to a second position P2 in which limiter 1222 is looped back onto itself making it possible to store the output useful value at this instant. In this case, output value X is frozen, avoiding taking into account a value U that might result from a calculation based on an erroneous signal X1 . . . XN.

Furthermore, limiter 1222 may be programmed with a constant k defining a slope or maximum transition rate. In this way, when switch 1220 toggles back to first position P1 (because from then on a signal SP no longer is transmitted), limiter 1222 assures that the output useful value s=X gradually returns (gradual transition according to factor k) to the input value e=U, if these two values are different at the moment of toggling back.

There now is described, with reference to FIGS. 5 and 8, a monitoring and passivation module 124 in the case of a triple redundancy (X1, X2, X3).

In this example, monitoring/passivation is based on a vote for the median signal among the input signals in order to obtain a reference value for monitoring, marked VR, obtained for example in a manner similar to FIG. 3. Of course, the mechanisms for obtaining the reference value for monitoring VR may be of another nature (for example, calculation of a linear function) and in particular may be different from the calculations implemented in calculation module 120. By using the same calculations, however, the technical complexity of implementation may be reduced.

Each input signal X1, X2, X3 then is compared to this monitoring reference value VR. When an overly significant deviation is detected, by comparison with a tolerance threshold value a, a positive detection signal is generated, for example a Boolean Bi (i=1, 2, 3) which goes to “true” in case of positive comparison. As soon as the comparison becomes negative again, the Boolean then goes back to “false”.

FIG. 5 shows an exemplary implementation of such a mechanism 1240₁ for monitoring input signal X1 only. Similar devices thus are provided for each of the other input signals.

Mechanism 1240₁ comprises a median value vote logic 200 (idem FIG. 3) receiving input signals X1, X2, X3 and generating the reference value for monitoring VR, comprises a subtracter 202 for calculating a deviation by subtracting the value of the input signal considered (here the signal X1) from this reference value VR, and finally comprises a comparator 204 for comparing this deviation (result of the subtraction) with the tolerance threshold α. The output of comparator 204 is the Boolean B1 (respectively B2, B3) which takes on the value “true” if the input X1 (resp. X2, X3) is too far from the reference value VR.

The Booleans Bi produced in this way at each clock cycle are entered as input of a logic OU 1242 the output of which corresponds to the passivation signal SP (see FIG. 6). In fact, as soon as a Boolean Bi goes to “true,” an input signal is considered as erroneous and the output useful signal X must be frozen. The signal SP makes it possible to trigger this freeze as described above.

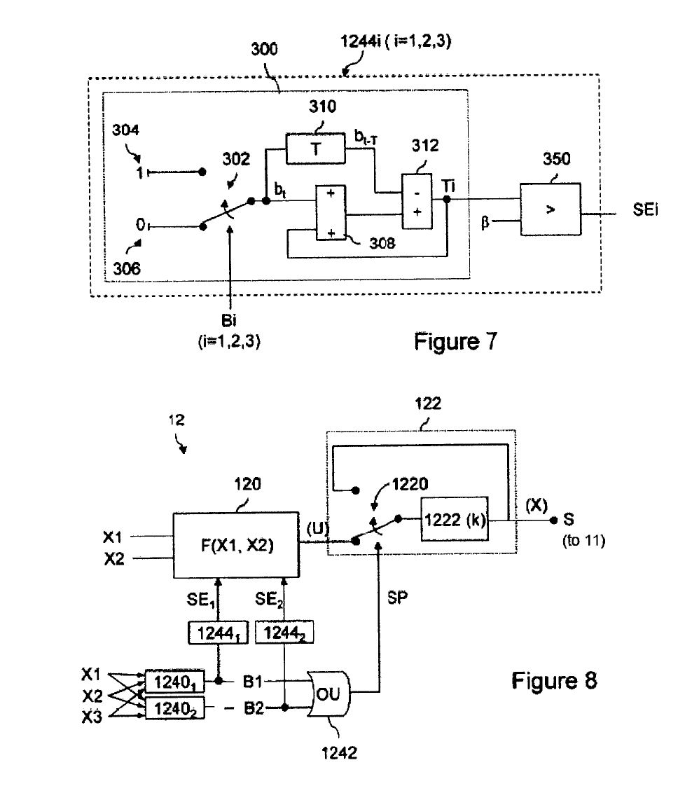

FIG. 7 schematically shows a module for exclusion 1244 of an input signal X1, X2, X3 (valid irrespective of the number of inputs) making it possible to exclude, from the calculation by module 120, a redundant input signal even if the corresponding source is undergoing erratic or oscillating failures.

Exclusion module 1244 receives as input the Boolean Bi associated with the input signal Xi that it is monitoring (generated in particular by the mechanisms of FIG. 5) and supplies as output an exclusion signal SEi which informs calculation module 120 if there is reason for excluding the input signal Xi from the calculations. In this case, corresponding source 20 is declared invalid and the calculations are performed only with signals originating from the remaining sources.

The mechanisms for exclusion by calculation module 120 remain standard and therefore will not be described in greater detail.

Furthermore, it will be noted that in case of exclusion of a signal, the latter also may be excluded from the monitoring, in particular that relating to the other still-valid input signals (for example excluded from voters 200 provided for these other signals).

Processing by exclusion module 1244 in particular is carried out at the same time as the processing operations of monitoring module 1240 at each clock cycle.

As many exclusion modules 1244 as there are input signals X1 . . . XN to be monitored are provided (in our example 3 modules 1244 for 3 input signals X1-X3).

Each exclusion module 1244 also is programmed with a delay T defining a sliding time window F for monitoring the sources and with an exclusion threshold β.

The threshold β defines the limit of the time spent by a signal in an erroneous state and accumulated in the time window, from which it is decided that the input signal Xi must be excluded from the calculation of the current useful value U.

The period T of the window F is in particular much greater than one clock cycle, for example on the order of several tens or even hundreds of cycles.

The period T of the window and the threshold β are fixed, on the one hand, in relation to an acceptability criterion of the flying laws for working with a freeze time percentage and, on the other hand, in relation to the robustness of the monitoring with regard to disturbances in the real environment when there is no failure.

In the example of the Figure, exclusion module 1244 comprises a counter 300 which counts, on the sliding time window F, a magnitude Ti representative of the time during which the input signal Xi is considered as erroneous (therefore when Bi=true), and comprises a comparator 350 comparing this magnitude Ti with the exclusion threshold value β.

For example if β corresponds to an error rate in time (for example 25%, 50%, 75% or 90% according to the desired sensitivity), the comparison consists in comparing Ti/T to β. The exclusion signal SEi then generated takes on the value “true” as soon as Ti/T>β, and otherwise the value “false.”

Preferably, this exclusion signal goes irreversibly to “true” so that an input signal excluded from calculation 120 cannot be reinstated later on. A zeroing of the system by an operator, however, makes it possible to bring all the exclusion signals SEi back to “false.”

Counter 300 comprises:
a switch 302 controlled by the Boolean Bi as input between a position connected to a register 304 equivalent to “1” and a position connected to a register 306 equivalent to “0.” As output of the switch at an instant t, there thus is a bit bₜ equivalent to either 1 or 0;
an adder 308 receiving, as input, the output value bₜ of switch 300 and the output value Ti of counter 300 at the previous clock-cycle instant t−1, so as to increment the counter according to the Boolean Bi;
a delay 310 equal to the period T of the sliding time window F, and receiving, as input, the output value bₜ of switch 300. This delay has the purpose of allowing elimination of the value that was incremented at t-T so as to assure that counter 300 counts only over the period of the sliding window F. As output of delay 310, at instant t there thus is the value b_{t-T};
a subtracter 312 for subtracting, at the output of adder 308, the delayed value as output of delay 310 and in this way producing the output value Ti of counter 300 for the current instant t. This subtraction assures that counting is done over the sliding period T alone.

Between two successive iterations of a clock cycle (between t−1 and t), one therefore has:
as output of adder 308: bₜ+Ti(t−1);
as output of delay 319: b_{t-T}; and
as output of subtracter 312: Ti(t)=Ti(t−1)+bₜ−b_{t-T}.

FIG. 8 illustrates a specific case where only two input signals among the three signals X1, X2, X3 are utilized for calculating the output useful signal X used by flying laws 11. Of course, this case may be extended to any use of j input signals among N(N>j) input redundant signals X1, . . . , XN.

In this example, calculation module 120 therefore uses the function F(X1, X2) a function only of X1 and X2, and only the two Booleans B1, B2 associated with the two input signals taken into account are used for running switch 1220 of output module 122. The Booleans B1, B2, however, are obtained by utilizing the three input signals X1-X3 in the calculation of the reference value VR (for example by a standard voter 200) within blocks 1240₁ and 1240₂.

Similarly, monitoring of erratic and/or oscillating behaviors of the sources by exclusion modules is carried out only for the signals X1 and X2: therefore only two modules 1244₁ and 1244₂ are provided, receiving respectively Boolean B1 and Boolean B2.

The behavior of the system of FIG. 8 therefore is similar to that explained above where one toggles between the modes M1 and M2 according to the detection of error in X1 and X2.

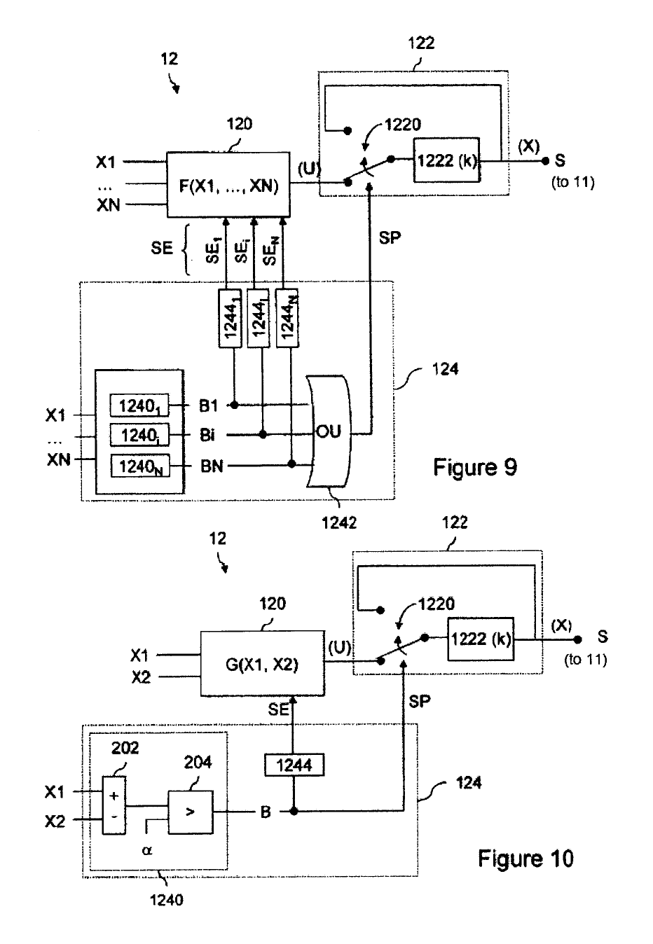

FIG. 9 schematically summarizes the above examples in a generic case of N input redundant signals.

There now is illustrated with reference to FIG. 10 the case of a double redundancy, that is to say where only two signals X1 and X2 are supplied by sources 20.

The two input redundant signals X1, X2 are compared with one another with the aid of a simple subtracter 202, before verifying, with the aid of comparator 204, whether the deviation between the two exceeds the tolerance threshold a. In case the threshold is exceeded, the output Boolean B goes to “true.” Otherwise, it is set at “false.”

It will be noted that this direct comparison of the two signals with one another is equivalent to a comparison of each one with a reference value VR calculated as an average of the two signals.

Similarly, an exclusion module 1244 as described above receives Boolean B generated in this way and produces as output a possible exclusion signal SE. In case of exclusion, the two input signals X1, X2 are excluded together from the calculations of module 120 because, since monitoring was carried out relative to one another, it is not possible to ascertain directly which one is the erroneous input signal.

Modules 120 and 122 may be similar to those described above, in particular taking into account the presence of only two input signals for the calculation G(X1, X2) of module 120.

As shown above, the invention offers passivation mechanisms making it possible to avoid any drift of the output useful signal by reason of a failure on one of the sources and any contamination of the output useful signal, as well as mechanisms for monitoring of sources making it possible to detect erratic and/or oscillating failures so as to exclude these sources from the calculations, if need be.

Implementation of an analysis of the behavior of failures over a sliding window period further assures that the output useful signal is not frozen for too long a time (at most the period of the threshold β).

The different means, modules and systems making up this invention may be, in whole or in part, implemented in software form and vice versa in the form of hardware circuits such as programmable logic circuits (type FPGA, for “field-programmable gate array” meaning system of gates programmable in situ).

The preceding examples are only embodiments of the invention, which is not limited thereto.

1. System for processing redundant signals, comprising:
inputs for receiving a plurality of redundant signals originating from sources;
a module for calculation of a current useful signal from input redundant signals;
a module for monitoring and passivation of sources, able to detect an erroneous signal taken into account in the said calculation, and to exclude the said erroneous signal from the calculation according to at least one criterion; and
an output for transmitting, as output useful signal, the said calculated current useful signal when no erroneous signal is detected;
characterized in that it further comprises a means for toggling, as soon as an erroneous signal is detected, to a freeze mode where the output useful signal is frozen as output, and for returning, as soon as an erroneous signal no longer is detected, to a transmission mode where the calculated current useful signal is transmitted as output useful signal.

2. System according to claim 1, comprising means for determining, on a sliding time window, a magnitude representative of the time during which the system is in freeze mode so as to exclude from the calculation, as soon as this magnitude reaches an exclusion threshold value, at least one signal detected as erroneous during the period of the said window.

3. System according to claim 2, in which the monitoring and passivation module is arranged for determining, on the sliding time window, a magnitude representative of the time during which a signal is detected as erroneous, so as to exclude from the calculation the signal detected as erroneous as soon as this magnitude reaches the said exclusion threshold value.

4. System according to claim 2, in which the monitoring and passivation module comprises a means able to generate, for at least one input signal, a Boolean representative of an erroneous or non-erroneous state of the input signal.

5. System according to claim 4, in which the Boolean of an input signal controls a counter counting the said magnitude on the sliding time window, and the monitoring and passivation module comprises a comparator of the counter with the exclusion threshold value, in order to generate, for the calculation module, a signal for exclusion of the input signal associated with the counter.

6. System according to claim 5, in which the counter comprises:
a switch controlled by the Boolean between a position connected to a register equivalent to “1” and a position connected to a register equivalent to “0”;
an adder receiving, as input, the output value of the switch and the output value of the counter, so as to increment the counter according to the Boolean;
a delay equal to the period of the sliding time window and receiving, as input, the output value of the switch;
a subtracter for subtracting, at the output of the adder, the delayed value as output of the delay and in this way producing an output value of the counter.

7. System according to one of claims 4 to 6, in which the means able to generate a Boolean representative of an erroneous state of an input signal comprises a comparator the output of which corresponds to the said Boolean and comparing the deviation between the said input signal and a reference signal calculated from the said input signals, with a tolerance threshold value.

8. System according to one of claims 4 to 6, in which the monitoring and passivation module comprises a logic function OU receiving, as input, the Booleans representative of an erroneous state of the input signals taken into account in the calculation, and generating, as output, a signal for control of the means for toggling.

9. System according to one of claims 1 to 6, in which the means for toggling comprises a switch controlled by the monitoring and passivation module, for switching, to the said output, the output useful signal for the freeze mode and the calculated current useful signal for the transmission mode.

10. System according to claim 9, in which the means for toggling further comprises a slope limiter able to carry out a controlled transition between the frozen output useful signal and the calculated current useful signal during a toggling to transmission mode.

11. Method for processing redundant signals, comprising the following steps:
receiving, as input, a plurality of redundant signals originating from sources;
calculating a current useful signal from input redundant signals;
detecting at least one erroneous signal taken into account in the said calculation, and excluding the said erroneous signal from the calculation when at least one criterion is met; and
transmitting, as output useful signal, the said calculated current useful signal when no error signal is detected;
characterized in that it comprises:
as soon as an erroneous signal is detected, a step consisting in freezing the output useful signal, and
as soon as an erroneous signal no longer is detected, a step consisting in going back to a transmission mode where the calculated current useful signal is transmitted as output useful signal.

12. Method according to the preceding claim, comprising a step of determining, on a sliding time window, a magnitude representative of the time during which a signal is erroneous, so as to exclude the erroneous signal from the calculation as soon as this magnitude reaches an exclusion threshold value.

13. System of electrical flight controls for an aircraft, comprising a computer receiving instructions and redundant signals originating from sources,
the said computer comprising a flying laws module receiving information items corresponding to the instructions and to at least one useful signal for generating control-surface commands for the aircraft, and comprising a processing system according to one of claims 1 to 6 able to process the received redundant signals in order to generate the said useful signal as input of the flying laws module.

14. Aircraft comprising a system of electrical flight controls according to the preceding claim.
